(19) United States
(12) Patent Application Publication
(10) Pub. No.: US 2024/0196676 A1
(43) Pub. Date: Jun. 13, 2024

(54) DISPLAY APPARATUS

(71) Applicant: Samsung Display Co., Ltd., Yongin-si (KR)

(72) Inventors: Kyoungjin Park, Yongin-si (KR); Daehyun Kim, Yongin-si (KR)

(73) Assignee: Samsung Display Co., Ltd., Yongin-si (KR)

(21) Appl. No.: 18/466,918

(22) Filed: Sep. 14, 2023

(30) Foreign Application Priority Data
Dec. 13, 2022 (KR) 10-2022-0174196

(51) Int. Cl. H10K 59/131; H10K 59/121

(52) U.S. Cl. CPC H10K 59/131; H10K 59/1213

(57) ABSTRACT

A display apparatus includes a first display element including a first pixel electrode and emitting light of a first color, a first conductive pattern layer and a second conductive pattern layer extending in a first direction and spaced apart from each other, and a first connection pattern layer extending in the first direction and electrically connecting the first conductive pattern layer to the second conductive pattern layer, the first connection pattern layer at least partially overlapping the first pixel electrode of the first display element, wherein the first conductive pattern layer and the second conductive pattern layer are disposed on a same layer between the first display element and the first connection pattern layer.

### CROSS-REFERENCE TO RELATED APPLICATION(S)

This application claims priority to and benefits of Korean Patent Application No. 10-2022-0174196, under 35 U.S.C. § 119, filed on Dec. 13, 2022, in the Korean Intellectual Property Office, the entire contents of which are incorporated herein by reference.

### BACKGROUND

### 1. Technical Field

One or more embodiments relate to a display apparatus.

### 2. Description of the Related Art

Display apparatuses display images based on data. A display apparatus is used as a screen for a small product such as a mobile phone or is used as a screen for a large product such as a television.

A display apparatus includes pixels that emit light by receiving an electrical signal to display an image to the outside. Each pixel includes a display element. For example, an organic light-emitting display apparatus includes an organic light-emitting diode (OLED) as a display element. In an organic light-emitting display apparatus, a thin-film transistor and an OLED are formed on a substrate, and the OLED emits light by itself.

As display apparatuses have recently been used for various purposes, various designs have been developed to improve the quality of display apparatuses.

### SUMMARY

One or more embodiments include a display apparatus capable of preventing or minimizing stains from occurring in a display area.

However, embodiments of the disclosure are not limited to those set forth herein. The above and other embodiments will become more apparent to one of ordinary skill in the art to which the disclosure pertains by referencing the detailed description of the disclosure given below.

Additional aspects will be set forth in part in the description which follows and, in part, will be apparent from the description, or may be learned by practice of the embodiments.

According to one or more embodiments, a display apparatus may include a first display element including a first pixel electrode and that emits light of a first color, a first conductive pattern layer and a second conductive pattern layer extending in a first direction and spaced apart from each other, and a first connection pattern layer extending in the first direction and electrically connecting the first conductive pattern layer to the second conductive pattern layer, the first connection pattern layer at least partially overlapping the first pixel electrode of the first display element, wherein the first conductive pattern layer and the second conductive pattern layer may be disposed on a same layer between the first display element and the first connection pattern layer.

The display apparatus may further include a first data line that transmits a first data voltage, the first data line including the first conductive pattern layer, the second conductive pattern layer, and the first connection pattern layer, and a first pixel circuit electrically connected to the first data line and that receives the first data voltage through the first data line and drives the first display element.

The first display element may include a first emission area that emits light of the first color, and in a plan view, the first pixel circuit and the first emission area of the first display element may be spaced apart from each other.

The display apparatus may further include a second display element including a second emission area and a second pixel electrode, the second emission area that emits light of a second color different from the first color, a second data line that transmits a second data voltage, the second data line including a third conductive pattern layer extending in the first direction, a fourth conductive pattern layer extending in the first direction and being spaced apart from the third conductive pattern layer, and a second connection pattern layer extending in the first direction, electrically connecting the third conductive pattern layer to the fourth conductive pattern layer, and at least partially overlapping the second pixel electrode of the second display element, and a second pixel circuit electrically connected to the second data line and that receives the second data voltage and drives the second display element, wherein the third conductive pattern layer and the fourth conductive pattern layer may be disposed on a same layer between the second display element and the second connection pattern layer, wherein, in a plan view, the second pixel circuit and the second emission area of the second display element may at least partially overlap each other.

The second pixel electrode of the second display element may include a first electrode portion and a second electrode portion, and a third electrode portion, wherein the first electrode portion and the second electrode portion may extend in the first direction and spaced apart from each other with the second data line between the first electrode portion and the second electrode portion, and the third electrode portion may electrically connect the first electrode portion to the second electrode portion and may at least partially overlap the second connection pattern layer.

The second emission area of the second display element may include a first light-emitting portion overlapping the first electrode portion in a plan view and a second light-emitting portion overlapping the second electrode portion in a plan view, wherein the first light-emitting portion overlaps the first pixel circuit in a plan view, and the second light-emitting portion may overlap the second pixel circuit in a plan view.

The third electrode portion may electrically connect an end portion of the first electrode portion to an end portion of the second electrode portion.

The third electrode portion may electrically connect a central portion of the first electrode portion to a central portion of the second electrode portion.

The display apparatus may further include a first shield electrode at least partially overlapping the first connection pattern layer, and a second shield electrode at least partially overlapping the second connection pattern layer, wherein the first shield electrode, the first conductive pattern layer, and the second conductive pattern layer may be disposed on a same layer, and the second shield electrode, the third conductive pattern layer, and the fourth conductive pattern layer may be disposed on a same layer.

The display apparatus may further include a first conductive line that transmits a first voltage, the first conductive line extending in the first direction, and a second conductive line that transmits a second voltage, the second conductive line extending in the first direction, wherein the first shield electrode may extend from the first conductive line in a second direction intersecting the first direction, and the second shield electrode may extend from the second conductive line in the second direction.

The first voltage and the second voltage may be different from each other.

The first pixel circuit may include a first transistor that controls a magnitude of a driving current flowing through the first display element, a second transistor that transmits the first data voltage to the first transistor in response to a first scan signal, and a third transistor that transmits an initialization voltage to the first pixel electrode of the first display element in response to a second scan signal, wherein a frequency of the first scan signal may be different from a frequency of the second scan signal.

The frequency of the second scan signal may be higher than the frequency of the first scan signal.

In a plan view, the first conductive pattern layer and the second conductive pattern layer may be spaced apart from the first pixel electrode of the first display element.

The display apparatus may further include a shield electrode that transmits a voltage, and at least partially overlaps the first connection pattern layer, wherein the shield electrode, the first conductive pattern layer, and the second conductive pattern layer may be disposed on a same layer.

The display apparatus may further include a conductive line that transmits the voltage, the conductive line extending in the first direction, wherein the shield electrode may extend from the conductive line in a second direction intersecting the first direction, and the shield electrode and the conductive line may be integral with each other.

According to one or more embodiments, a display apparatus may include a data line including a first conductive pattern layer extend in a first direction, a second conductive pattern layer extend in the first direction and spaced apart from the first conductive pattern layer, and a connection pattern layer extending in the first direction and electrically connecting the first conductive pattern layer to the second conductive pattern layer, and a pixel electrode including a first electrode portion and a second electrode portion spaced apart from each other with the data line between the first electrode portion and the second electrode portion, and a third electrode portion electrically connecting the first electrode portion to the second electrode portion and at least partially overlapping the connection pattern layer, wherein the first conductive pattern layer and the second conductive pattern layer may be disposed on a same layer between the pixel electrode and the connection pattern layer.

The display apparatus may further include a display element including the pixel electrode, and a pixel circuit that drives the display element, wherein the pixel circuit may include a first transistor that controls a magnitude of a driving current flowing through the display element, a second transistor that electrically connects the data line to the first transistor in response to a first scan signal, and a third transistor that transmits an initialization voltage to the pixel electrode of the display element in response to a second scan signal, and a frequency of the first scan signal may be different from a frequency of the second scan signal.

The frequency of the second scan signal may be higher than the frequency of the first scan signal.

In a plan view, the pixel circuit may at least partially overlap the first electrode portion or the second electrode portion.

The third electrode portion may electrically connect an end portion of the first electrode portion to an end portion of the second electrode portion.

The third electrode portion may electrically connect a central portion of the first electrode portion to a central portion of the second electrode portion.

In a plan view, the first conductive pattern layer and the second conductive pattern layer may be spaced apart from the pixel electrode.

The display apparatus may further include a shield electrode that transmits a voltage and at least partially overlaps the connection pattern layer.

The display apparatus may further include a conductive line that transmits the voltage, the conductive line extending in the first direction, wherein the shield electrode may extend from the conductive line in a second direction intersecting the first direction, and the shield electrode and the conductive line may be integral with each other.

Other aspects, features, and advantages of the disclosure will become more apparent from the detailed description, the claims, and the drawings.

These general and specific embodiments may be implemented by using a system, a method, a computer program, or a combination thereof.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic plan view illustrating a display apparatus according to an embodiment;

FIG. 2 is a schematic diagram of an equivalent circuit illustrating a pixel included in the display apparatus of FIG. 1;

FIG. 3 is an enlarged schematic plan view illustrating a portion of a display apparatus according to an embodiment;

FIG. 4 is a schematic cross-sectional view illustrating a pixel electrode and a data line of FIG. 3, taken along line I-I′;

FIG. 5 is a schematic cross-sectional view illustrating a pixel electrode and a data line of FIG. 3, taken along line I-I′;

FIG. 6 is a schematic cross-sectional view illustrating a pixel electrode and a data line of FIG. 3, taken along line I-I′;

FIG. 7 is a schematic view illustrating an operation of a display apparatus according to an embodiment;

FIG. 8 is an enlarged schematic plan view illustrating a portion of a display apparatus according to an embodiment;

FIG. 9 is a schematic cross-sectional view illustrating a pixel electrode, a data line, and a shield electrode of FIG. 8, taken along line II-II′;

FIG. 10 is an enlarged schematic plan view illustrating a portion of a display apparatus according to an embodiment;

FIG. 11 is a schematic cross-sectional view illustrating a pixel electrode and a data line of FIG. 10, taken along line III-III′;

FIG. 12 is an enlarged schematic plan view illustrating a portion of a display apparatus according to an embodiment;

FIG. 13 is an enlarged schematic plan view illustrating a portion of a display apparatus according to an embodiment;

FIG. 14 is a schematic cross-sectional view illustrating a pixel electrode, a data line, and a shield electrode of FIG. 13, taken along line IV-IV′;

FIG. 15 is an enlarged schematic plan view illustrating a portion of a display apparatus according to an embodiment; and

FIG. 16 is an enlarged schematic plan view illustrating a portion of a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the x-axis, the y-axis, and the z-axis are not limited to three axes of a rectangular coordinate system, such as the x, y, and z axes, and may be interpreted in a broader sense. For example, the x-axis, the y-axis, and the z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

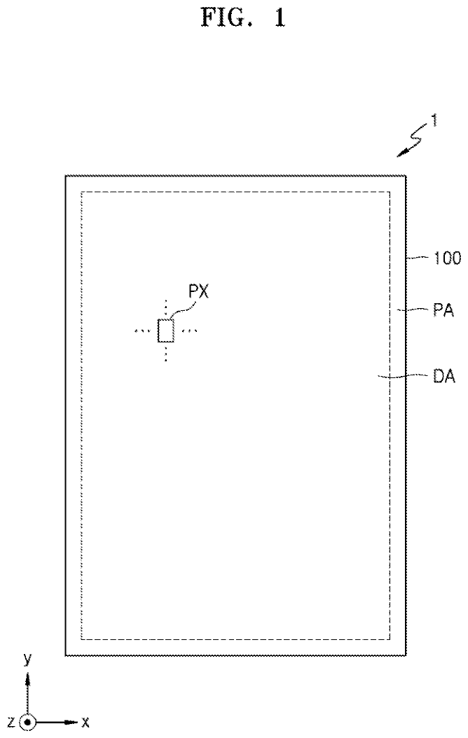

FIG. 1 is a schematic plan view of a display apparatus according to an embodiment.

Referring to FIG. 1, a display apparatus 1 may include a display area DA where an image is displayed and a peripheral area PA surrounding at least a part of the display area DA. The display apparatus 1 may provide an image to the outside by using light emitted from the display area DA. Because the display apparatus 1 includes a substrate 100, the substrate 100 may include the display area DA and the peripheral area PA. For example, the display area DA and the peripheral area PA may be defined on the substrate 100.

The substrate 100 may include any of various materials, for example, glass, a metal, or plastic. According to an embodiment, the substrate 100 may include a flexible material. The flexible material may include a material that is well bendable, foldable, or rollable. The substrate 100 including the flexible material may include ultra-thin glass, metal, or plastic.

The display area DA may have a rectangular shape as shown in FIG. 1. In another example, the display area DA may have a polygonal shape (e.g., a triangular shape, a pentagonal shape, or a hexagonal shape), a circular shape, an elliptical shape, or an irregular shape.

Pixels PX including various display elements such as organic light-emitting diodes (OLEDs) may be positioned in the display area DA of the substrate 100. Pixels PX may be provided (or formed), and the pixels PX may be arranged in any of various types such as a stripe type, a PenTile® type, or a mosaic type to form an image. Hereinafter, each pixel PX may include a sub-pixel that emits light of a different color, and may be one of, for example, a red sub-pixel, a green sub-pixel, and a blue sub-pixel.

Although the display apparatus 1 according to an embodiment is an organic light-emitting display apparatus, the display apparatus is not limited thereto. In another example, the display apparatus 1 may be an inorganic light-emitting display apparatus or an inorganic electroluminescent (EL) display apparatus, or a quantum dot light-emitting display apparatus. For example, an emission layer of a display element provided in the display apparatus may include an organic material, may include an inorganic material, may include quantum dots, may include an organic material and quantum dots, may include an inorganic material and quantum dots, or may include an organic material, an inorganic material, and quantum dots.

The peripheral area PA of the substrate 100 positioned (or disposed) around the display area DA may be an area where an image is not displayed. Various wirings for transmitting electric signals to be applied to the display area DA, and pads to which a printed circuit board or a driver integrated circuit (IC) chip is attached may be positioned in the peripheral area PA.

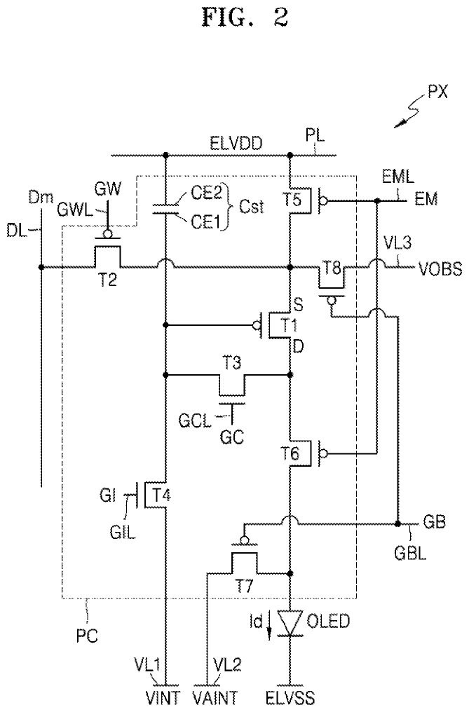

FIG. 2 is a schematic diagram of an equivalent circuit of a pixel included in the display apparatus of FIG. 1.

Referring to FIG. 2, a pixel (or a single pixel) PX may include a pixel circuit PC and a display element electrically connected to the pixel circuit PC. The display element may be an organic light-emitting diode OLED including an anode (or a pixel electrode) and a cathode (or a counter electrode).

For example, the pixel circuit PC may include first to eighth transistors T1 to T8 and a storage capacitor Cst, as shown in FIG. 2. The first to eighth transistors T1 to T8 and the storage capacitor Cst may be connected (e.g., electrically connected) to first to fourth scan lines GWL, GCL, GIL, and GBL that respectively transmit first to fourth scan signals GW, GC, GI, and GB, a data line DL that transmits a data voltage Dm, an emission control line EML that transmits an emission control signal EM, a power supply line PL that transmits a first driving voltage ELVDD, a first voltage line VL1 that transmits a first initialization voltage VINT, a second voltage line VL2 that transmits a second initialization voltage VAINT, a third voltage line VL3 that transmits a bias voltage VOBS, and a common electrode to which a second driving voltage ELVSS is applied.

The first transistor T1 may be a driving transistor in which a magnitude of drain current is determined according to a gate-source voltage, and the second to eighth transistors T2 to T8 may be switching transistors that are turned on or off according to a gate-source voltage, substantially, a gate voltage. The first to eighth transistors T1 to T8 may be thin-film transistors.

In an embodiment, some of the first to eighth transistors T1 to T8 may be provided as n-channel MOSFETs (NMOSs) and the rest may be provided as p-channel MOSFETs (PMOSs). For example, as shown in FIG. 2, the third transistor T3 and the fourth transistor T4 may be provided as NMOSs, and the first transistor T1, the second transistor T2, the fifth transistor T5, the sixth transistor T6, the seventh transistor T7, and the eighth transistor T8 may be provided as PMOSs.

In another example, the first to eighth transistors T1 to T8 may be provided as PMOSs. In another example, the first to eighth transistors T1 to T8 may be provided as NMOSs.

In an embodiment, some semiconductor layers of the first to eighth transistors T1 to T8 may be formed of low temperature polysilicon (LTPS), and other semiconductor layers may be formed of an oxide semiconductor (e.g., IGZO).

In another example, each of the first to eighth transistors T1 to T8 may include a semiconductor layer including silicon. For example, each of the first to eighth transistors T1 to T8 may include a semiconductor layer including LTPS. A polysilicon material may have a high electron mobility (e.g., 100 cm²/Vs or more), and thus may have low energy consumption and excellent reliability.

In another example, semiconductor layers of the first to eighth transistors T1 to T8 may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the semiconductor layer may be an InSnZnO (ITZO) semiconductor layer or an InGaZnO (IGZO) semiconductor layer.

The storage capacitor Cst may be connected between the power supply line PL and a gate of the first transistor T1. The storage capacitor Cst may include a lower electrode CE1 connected to the gate of the first transistor T1 and an upper electrode CE2 connected to the power supply line PL.

The first transistor T1 may control a magnitude of a driving current Id flowing from the power supply line PL to the organic light-emitting diode OLED according to a gate-source voltage. The first transistor T1 may include the gate connected to the lower electrode CE1 of the storage capacitor Cst, a source S connected to the power supply line PL through the fifth transistor T5, and a drain D connected to the organic light-emitting diode OLED through the sixth transistor T6.

The first transistor T1 may output the driving current Id to the organic light-emitting diode OLED according to a gate-source voltage. A magnitude of the driving current Id may be determined based on a difference between a threshold voltage and the gate-source voltage of the first transistor T1. The organic light-emitting diode OLED may receive the driving current Id from the first transistor T1, and may emit light at a luminance according to the magnitude of the driving current Id.

The second transistor T2 may connect (e.g., electrically connect) the data line DL to the first transistor T1 in response to the first scan signal GW. The second transistor T2 may transmit the data voltage Dm to the first transistor T1 in response to the first scan signal GW. For example, the second transistor T2 may connect (e.g., electrically connect) the data line DL to the source S of the first transistor T1 in response to the first scan signal GW. The second transistor T2 may transmit the data voltage Dm to the source S of the first transistor T1 in response to the first scan signal GW.

The third transistor T3 may connect (e.g., electrically connect) the gate and the drain D of the first transistor T1 to each other in response to the second scan signal GC. The third transistor T3 may be connected in series between the gate and the drain D of the first transistor T1.

The fourth transistor T4 may connect (e.g., electrically connect) the first voltage line VL1 to the gate of the first transistor T1 in response to the third scan signal GI. The fourth transistor T4 may transmit the first initialization voltage VINT to the gate of the first transistor T1 in response to the third scan signal GI.

The fifth transistor T5 may connect (e.g., electrically connect) the power supply line PL to the source S of the first transistor T1 in response to the emission control signal EM. The fifth transistor T5 may connect (e.g., electrically connect) the power supply line PL to the source S of the first transistor T1 in response to the emission control signal EM. The fifth transistor T5 may transmit the first driving voltage ELVDD to the source S of the first transistor T1 in response to the emission control signal EM.

The sixth transistor T6 may connect (e.g., electrically connect) the drain D of the first transistor T1 to the anode of the organic light-emitting diode OLED in response to the emission control signal EM. The sixth transistor T6 may connect (e.g., electrically connect) the drain D of the first transistor T1 to the anode of the organic light-emitting diode OLED in response to the emission control signal EM.

Although the fifth transistor T5 and the sixth transistor T6 operate in response to the same emission control signal EM in FIG. 2, in another example, the fifth transistor T5 and the sixth transistor T6 may operate in response to different emission control signals.

The seventh transistor T7 may connect (e.g., electrically connect) the second voltage line VL2 to the anode of the organic light-emitting diode OLED in response to the fourth scan signal GB. The seventh transistor T7 may transmit the second initialization voltage VAINT to the anode of the organic light-emitting diode OLED in response to the fourth scan signal GB.

The eighth transistor T8 may connect (e.g., electrically connect) the third voltage line VL3 to the source S of the first transistor T1 in response to the fourth scan signal GB. The eighth transistor T8 may transmit the bias voltage VOBS to the source S of the first transistor T1 in response to the fourth scan signal GB.

Although the seventh transistor T7 and the eighth transistor T8 operate in response to the same fourth scan signal GB in FIG. 2, in another example, the seventh transistor T7 and the eighth transistor T8 may operate in response different scan signals.

In an embodiment, a frequency of the first scan signal GW may be different from a frequency of the fourth scan signal GB. For example, a frequency of the fourth scan signal GB may be higher than a frequency of the first scan signal GW. A frequency of the fourth scan signal GB may be twice a frequency of the first scan signal GW.

In an embodiment, the second scan signal GC may be substantially synchronized with the first scan signal GW. The third scan signal GI may be substantially synchronized with the first scan signal GW of a previous row.

Although the pixel circuit PC includes eight transistors and one capacitor in FIG. 2, the number of transistors and the number of capacitors included in the pixel circuit PC may be changed. For example, the pixel circuit PC may include seven transistors and one capacitor.

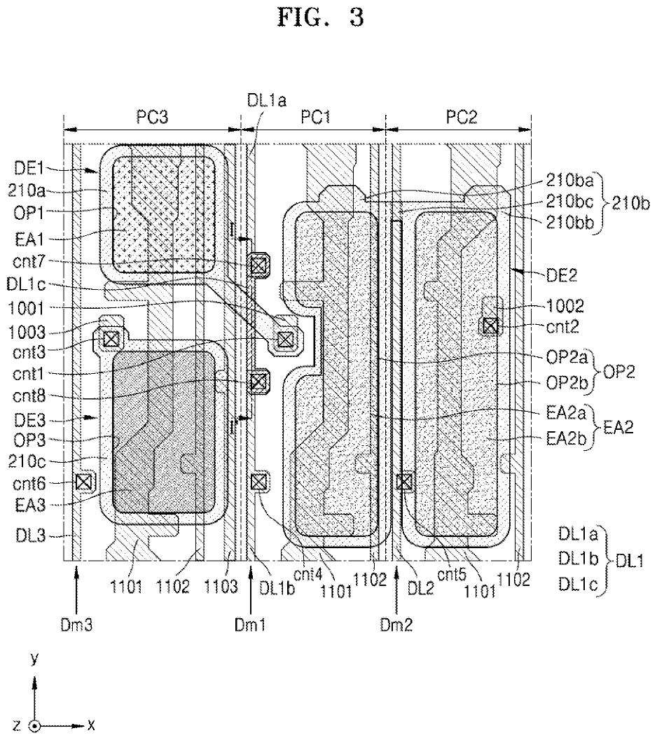

FIG. 3 is an enlarged schematic plan view of a portion of a display apparatus according to an embodiment.

Referring to FIG. 3, the display apparatus 1 may include first to third pixel circuits PC1. PC2, and PC3, first to third display elements DE1, DE2, and DE3, first to third data lines DL1, DL2, and DL3, first to third connection electrodes 1001, 1002, and 1003, and first to third conductive lines 1101, 1102, and 1103.

The first to third pixel circuits PC1, PC2, and PC3 may be electrically connected to the first to third display elements DE1, DE2, and DE3, respectively. The first to third pixel circuits PC1, PC2, and PC3 may respectively drive the first to third display elements DE1, DE2, and DE3. For example, the first pixel circuit PC1 may be connected (e.g., electrically connected) to the first display element DE1 through the first connection electrode 1001 and a first contact hole cnt1. The second pixel circuit PC2 may be connected (e.g., electrically connected) to the second display element DE2 through the second connection electrode 1002 and a second contact hole cnt2. The third pixel circuit PC3 may be connected (e.g., electrically connected) to the third display element DE3 through the third connection electrode 1003 and a third contact hole cnt3. The description of the pixel circuit PC of FIG. 2 may be applied to the first to third pixel circuits PC1, PC2, and PC3.

The first display element DE1 may emit light of a first color and may include a first pixel electrode 210a. The second display element DE2 may emit light of a second color and may include a second pixel electrode 210b. The third display element DE3 may emit light of a third color and may include a third pixel electrode 210c. The first to third pixel electrodes 210a, 210b, and 210c may be semi-transmissive electrodes, transmissive electrodes or reflective electrodes. In an embodiment, the first color may be red, the second color may be blue, and the third color may be green.

In an embodiment, the second pixel electrode 210b of the second display element DE2 may include a first electrode portion 210ba, a second electrode portion 210bb, and a third electrode portion 210bc. The first electrode portion 210ba and the second electrode portion 210bb may extend in a first direction (e.g., +y-axis direction). The first electrode portion 210ba and the second electrode portion 210bb may be spaced apart from each other with the second data line DL2 therebetween. The third electrode portion 210bc may connect (e.g., electrically connect) the first electrode portion 210ba to the second electrode portion 210bb. The third electrode portion 210bc may connect (e.g., electrically connect) an end portion of the first electrode portion 210ba to an end portion of the second electrode portion 210bb. Because only the third electrode portion 210bc overlaps the second data line DL2, an overlapping ratio (or overlapping size/area) between the second data line DL2 and the second pixel electrode 210b may decrease.

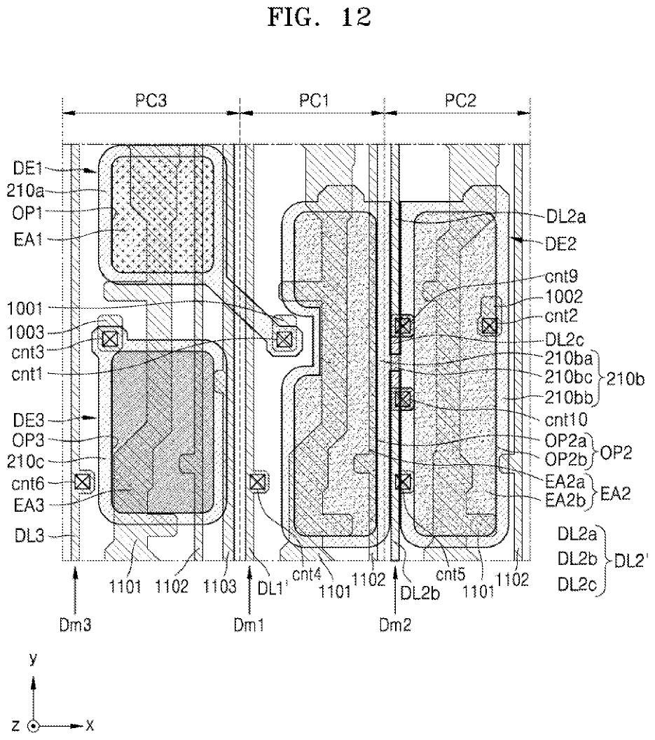

Although the third electrode portion 210bc connects an end portion of the first electrode portion 210ba to an end portion of the second electrode portion 210bb in FIG. 3, in another example, as shown in FIG. 12, the third electrode portion 210bc may connect (e.g., electrically connect) a central portion of the first electrode portion 210ba to a central portion of the second electrode portion 210bb.

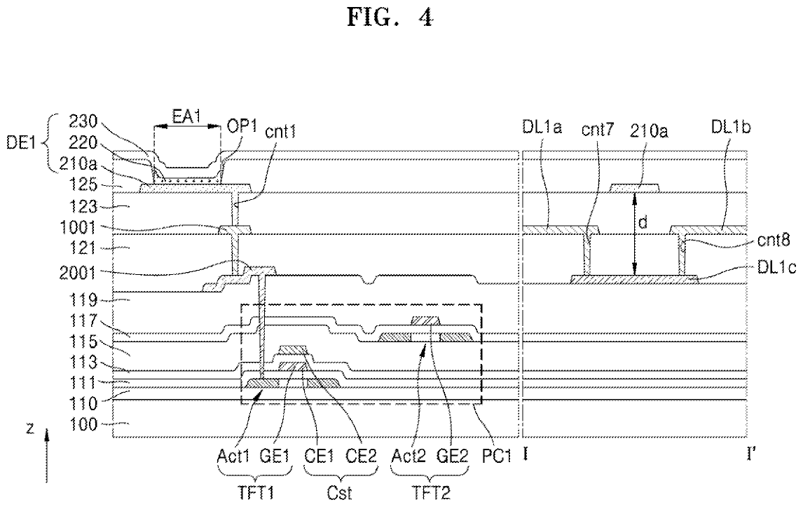

The first display element DE1 may include a first emission area EA1 emitting light of the first color, the second display element DE2 may include a second emission area EA2 emitting light of the second color, and the third display element DE3 may include a third emission area EA3 emitting light of the third color. The first emission area EA1 may be defined by a first opening OP1 through which at least a part of the first pixel electrode 210a is exposed. The second emission area EA2 may bd defined by a second opening OP2 through which at least a part of the second pixel electrode 210b is exposed. The third emission area EA3 may be defined by a third opening OP3 through which at least a part of the third pixel electrode 210c is exposed. The first to third openings OP1, OP2, and OP3 may be formed in a pixel-defining film 125 of FIG. 4 described below.

In an embodiment, the second emission area EA2 of the second display element DE2 may include a first light-emitting portion EA2a and a second light-emitting portion EA2b. In a plan view, the first light-emitting portion EA2a may overlap the first electrode portion 210ba, and the second light-emitting portion EA2b may overlap the second electrode portion 210bb. The first light-emitting portion EA2a may be defined by a second-first opening OP2a through which at least a part of the first electrode portion 210ba is exposed, and the second light-emitting portion EA2b may be defined by a second-second opening OP2b through which at least a part of the second electrode portion 210bb is exposed.

In an embodiment, in a plan view, an emission area of a display element may be spaced apart from or at least partially overlap a pixel circuit that drives the display element. For example, as shown in FIG. 3, in a plan view, the first emission area EA1 of the first display element DE1 may be spaced apart from the first pixel circuit PC1. The first emission area EA1 of the first display element DE1 may not overlap the first pixel circuit PC1. The first emission area EA1 of the first display element DE1 may overlap the third pixel circuit PC3. The second emission area EA2 of the second display element DE2 may at least partially overlap the first pixel circuit PC1 and the second pixel circuit PC2. The first light-emitting portion EA2a of the second emission area EA2 may overlap the first pixel circuit PC1, and the second light-emitting portion EA2b of the second emission area EA2 may overlap the second pixel circuit PC2. The third emission area EA3 may overlap the third pixel circuit PC3.

Although the first to third display elements DE1, DE2, and DE3 are arranged in an s-stripe type in FIG. 3, in another example, the first to third display elements DE1, DE2, and DE3 may be arranged in any of various types such as a stripe type or a PenTile® type.

The first to third data lines DL1, DL2, and DL3 may extend in the first direction (e.g., +y-axis direction). First to third data voltages Dm1, Dm2, and Dm3 may be respectively applied to the first to third data lines DL1, DL2, and DL3. The first data line DL1 may be connected (e.g., electrically connected) to the first pixel circuit PC1 through a fourth contact hole cnt4, the second data line DL2 may be connected (e.g., electrically connected) to the second pixel circuit PC2 through a fifth contact hole cnt5, and the third data line DL3 may be connected (e.g., electrically connected) to the third pixel circuit PC3 through a sixth contact hole cnt6. The first pixel circuit PC1 may receive the first data voltage Dm1 from the first data line DL1, the second pixel circuit PC2 may receive the second data voltage Dm2 from the second data line DL2, and the third pixel circuit PC3 may receive the third data voltage Dm3 from the third data line DL3.

In an embodiment, the first data line DL1 may include a first conductive pattern layer DL1a, a second conductive pattern layer DL1b, and a first connection pattern layer DL1c. The first conductive pattern layer DL1a and the second conductive pattern layer DL1b may extend in the first direction (e.g., +y-axis direction) and may be spaced apart from each other. The first connection pattern layer DL1c may extend in the first direction (e.g., +y-axis direction) to connect (e.g., electrically connect) the first conductive pattern layer DL1a to the second conductive pattern layer DL1b. An end portion of the first connection pattern layer DL1c may be connected (e.g., electrically connected) to the first conductive pattern layer DL1a through a seventh contact hole cnt7, and another end portion of the first connection pattern layer DL1c may be connected (e.g., electrically connected) to the second conductive pattern layer DL1b through an eighth contact hole cnt8. In a plan view, the first conductive pattern layer DL1a and the second conductive pattern layer DL1b may be spaced apart from (or may not overlap) the first pixel electrode 210a, and the first connection pattern layer DL1c may at least partially overlap the first pixel electrode 210a.

As described below with reference to FIG. 4, the first conductive pattern layer DL1a and the second conductive pattern layer DL1b may be positioned on the same layer (e.g., sixth insulating layer 121) between the first display element DE1 and the first connection pattern layer DL1c. The first conductive pattern layer DL1a and the second conductive pattern layer DL1b may be positioned on the same layer (e.g., sixth insulating layer 121) between the first pixel electrode 210a and the first connection pattern layer DL1c. For example, a distance between the first data line DL1 and the first pixel electrode 210a may increase at a portion where the first data line DL1 and the first pixel electrode 210a overlap each other. Thus, a capacitance value formed between the first data line DL1 and the first pixel electrode 210a may decrease.

The first to third pixel circuits PC1, PC2, and PC3 and the first to third display elements DE1, DE2, and DE3 of FIG. 3 may constitute a unit (or a single unit). There may be a plurality of units, and the plurality of units may be arranged in a matrix. The first data line DL1 may include the first connection pattern layer DL1c overlapping the first pixel electrode 210a of the first display element DE1 included in each of the plurality of units. That is, there may be a plurality of first connection pattern layers DL1c, and the plurality of first connection pattern layers DL1c may be arranged in a matrix.

The first to third conductive lines 1101, 1102, and 1103 may extend in the first direction (e.g., +y-axis direction). The first to third conductive lines 1101, 1102, and 1103 may transmit preset (or certain) voltages to the first to third pixel circuits PC1, PC2, and PC3. For example, the first driving voltage ELVDD of FIG. 2 may be applied to the first conductive line 1101. The second driving voltage ELVSS of FIG. 2 may be applied to the second conductive line 1102. The first initialization voltage VINT, the second initialization voltage VAINT, or the bias voltage VOBS of FIG. 2 may be applied to the third conductive line 1103.

FIG. 4 is a cross-sectional view of a pixel electrode and a data line of FIG. 3, taken along line I-I′. FIG. 4 illustrates the first pixel circuit PC1 and the first display element DE1 of FIG. 3. Although FIG. 4 is described based on the first pixel circuit PC1 and the first display element DE1, the description may be applied to the second pixel circuit PC2, the third pixel circuit PC3, the second display element DE2, and the third display element DE3 of FIG. 3.

Referring to FIG. 4, the first pixel circuit PC1 may include a first thin-film transistor TFT1, a second thin-film transistor TFT2, and a storage capacitor Cst. The first thin-film transistor TFT1 may include a first semiconductor layer Act1 and a first gate electrode GE1, the second thin-film transistor TFT2 may include a second semiconductor layer Act2 and a second gate electrode GE2, and the storage capacitor Cst may include a lower electrode CE1 and an upper electrode CE2. The first thin-film transistor TFT1 may correspond to the first transistor T1 of FIG. 2, and the second thin-film transistor TFT2 may correspond to the third transistor T3 or the fourth transistor T4 of FIG. 2.

The first conductive pattern layer DL1a and the second conductive pattern layer DL1b may be positioned on the same layer (e.g., sixth insulating layer 121) between the first display element DE1 and the first connection pattern layer DL1c. The first conductive pattern layer DL1a and the second conductive pattern layer DL1b may be positioned on the same layer (e.g., sixth insulating layer 121) between the first pixel electrode 210a and the first connection pattern layer DL1c. For example, a distance d between the first data line DL1 and the first pixel electrode 210a may increase at a portion where the first data line DL1 and the first pixel electrode 210a overlap each other. Thus, a capacitance value formed between the first data line DL1 and the first pixel electrode 210a may decrease.

Elements included in a display apparatus will be described according to a stacked structure with reference to FIG. 4.

The substrate 100 may include a glass material, a ceramic material, a metal material, or a flexible or bendable material. In case that the substrate 100 is flexible or bendable, the substrate 100 may include a polymer resin such as a polyethersulfone (PES), polyacrylate, polyetherimide, polyethylene naphthalate (PEN), polyethylene terephthalate, polyphenylene sulfide, polyarylate, polyimide, polycarbonate, or cellulose acetate propionate. The substrate 100 may have a single structure or a multi-layer structure including the above material, and in case that the substrate 100 has a multi-layer structure, the substrate 100 may further include an inorganic layer. In some embodiments, the substrate 100 may have a structure including an organic material, an inorganic material, and an organic material.

A buffer layer 110 may reduce or block penetration of a foreign material, moisture, or external air from the bottom (or lower surface) of the substrate 100, and may planarize the substrate 100. The buffer layer 110 may include an inorganic material such as oxide or nitride, an organic material, or a combination of an organic material and an inorganic material, and may have a single structure or a multi-layer structure including an inorganic material and an organic material.

A barrier layer may be further provided between the substrate 100 and the buffer layer 110. The barrier layer may prevent or minimize penetration of impurities from the substrate 100 or the like into the first semiconductor layer Act1 and the second semiconductor layer Act2. The barrier layer may include an inorganic material such as oxide or nitride, an organic material, or a combination of an organic material and an inorganic material, and may have a single structure or a multi-layer structure including an inorganic material and an organic material.

The first semiconductor layer Act1 may be positioned on the buffer layer 110. The first semiconductor layer Act1 may include amorphous silicon or polysilicon. The first semiconductor layer Act1 may include a channel region, and a source region and a drain region positioned on sides (e.g., opposite sides) of the channel region. The source region and the drain region may be regions doped by adding dopants. The first semiconductor layer Act1 may have a single structure or a multi-layer structure.

A first insulating layer 111 and a second insulating layer 113 may be stacked on the substrate 100 to cover the first semiconductor layer Act1. Each of the first insulating layer 111 and the second insulating layer 113 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

The first gate electrode GE1 may be positioned on the first insulating layer 111. The first gate electrode GE1 may at least partially overlap the first semiconductor layer Act1. The first gate electrode GE1 may include a conductive material including molybdenum (Mo), aluminum (Al), copper (Cu), or titanium (Ti), and may have a single structure or a multi-layer structure including the above material. For example, the first gate electrode GE1 may have a single-layer structure including Mo.

The upper electrode CE2 may be positioned on the second insulating layer 113. The upper electrode CE2 may include a conductive material including molybdenum (Mo), aluminum (Al), copper (Cu), or titanium (Ti), and may have a single structure or a multi-layer structure including the above material. For example, the upper electrode CE2 may have a single-layer structure including Mo.

In an embodiment, the storage capacitor Cst may include the lower electrode CE1 and the upper electrode CE2, and may overlap the first thin-film transistor TFT1 as shown in FIG. 4. For example, the first gate electrode GE1 of the first thin-film transistor TFT1 may function as the lower electrode CE1 of the storage capacitor Cst. In another example, the storage capacitor Cst may not overlap the first thin-film transistor TFT1 and may be separately positioned.

The upper electrode CE2 of the storage capacitor Cst may overlap the lower electrode CE1 with the second insulating layer 113 therebetween, to form capacitance. For example, the second insulating layer 113 may function as a dielectric layer of the storage capacitor Cst.

A third insulating layer 115 may be positioned on the second insulating layer 113 to cover the upper electrode CE2. The third insulating layer 115 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

The second semiconductor layer Act2 may be positioned on the third insulating layer 115. The second semiconductor layer Act2 may include an oxide semiconductor material. The second semiconductor layer Act2 may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn).

For example, the second semiconductor layer Act2 may be an InSnZnO (ITZO) semiconductor layer or an InGaZnO (IGZO) semiconductor layer. Because an oxide semiconductor has a wide band gap (e.g., about 3.1 eV), a high carrier mobility, and low leakage current, a voltage drop may not be large even in case that a driving time is long. Accordingly, a luminance change due to a voltage drop may not be large even during low-frequency operation.

The second semiconductor layer Act2 may include a channel region, and a source region and a drain region positioned on sides (e.g., opposite sides) of the channel region The second semiconductor layer Act2 may have a single structure or a multi-layer structure.

A fourth insulating layer 117 may be positioned on the third insulating layer 115 to cover the second semiconductor layer Act2. The fourth insulating layer 117 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

Although the fourth insulating layer 117 is positioned over an entire surface of the substrate 100 to cover the second semiconductor layer Act2 in FIG. 4, in another example, the fourth insulating layer 117 may be patterned to overlap a part of the second semiconductor layer Act2. For example, the fourth insulating layer 117 may be patterned to overlap the channel region of the second semiconductor layer Act2.

The second gate electrode GE2 may be positioned on the fourth insulating layer 117. The second gate electrode GE2 may at least partially overlap the second semiconductor layer Act2. The second gate electrode GE2 may include a conductive material including molybdenum (Mo), aluminum (Al), copper (Cu), or titanium (Ti), and may have a single structure or a multi-layer structure including the above material. For example, the second gate electrode GE2 may have a single-layer structure including Mo.

Although the first thin-film transistor TFT1 and the second thin-film transistor TFT2 are positioned on different layers in FIG. 4, in another example, the first thin-film transistor TFT1 and the second thin-film transistor TFT2 may be positioned on the same layer. For example, the second semiconductor layer Act2 of the second thin-film transistor TFT2 may be positioned between the buffer layer 110 and the first insulating layer 111, and the second gate electrode GE2 may be positioned between the first insulating layer 111 and the second insulating layer 113. For example, the first semiconductor layer Act1 of the first thin-film transistor TFT1 and the second semiconductor layer Act2 of the second thin-film transistor TFT2 may include the same material. In another example, some insulating layers may be omitted.

A fifth insulating layer 119 may be positioned on the fourth insulating layer 117 to cover the second gate electrode GE2. The fifth insulating layer 119 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

A fourth connection electrode 2001 and the first connection pattern layer DL1c may be positioned on the fifth insulating layer 119. Each of the fourth connection electrode 2001 and the first connection pattern layer DL1c may include a conductive material including molybdenum (Mo), aluminum (Al), copper (Cu), or titanium (Ti), and may have a single structure or a multi-layer structure including the above material. For example, each of the fourth connection electrode 2001 and the first connection pattern layer DL1c may have a multi-layer structure including Ti/Al/Ti.

The fourth connection electrode 2001 may be connected (e.g., electrically connected) to the first semiconductor layer Act1 through contact holes formed in the first to fifth insulating layers 111, 113, 115, 117, and 119. A part of the fourth connection electrode 2001 may be buried (or filled) in the contact holes, and the fourth connection electrode 2001 and the first semiconductor layer Act1 may be connected (e.g., electrically connected) to each other.

A sixth insulating layer 121 and a seventh insulating layer 123 may be stacked on the fifth insulating layer 119. Each of the sixth insulating layer 121 and the seventh insulating layer 123 may have a single structure or a multi-layer structure including an organic material to provide a flat top surface (or flat upper surface). For example, each of the sixth insulating layer 121 and the seventh insulating layer 123 may include benzocyclobutene (BCB), polyimide, hexamethyldisiloxane (HMDSO), a general-purpose polymer such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The first connection electrode 1001, the first conductive pattern layer DL1a, and the second conductive pattern layer DL1b may be positioned on the sixth insulating layer 121. Each of the first connection electrode 1001, the first conductive pattern layer DL1a, and the second conductive pattern layer DL1b may include a conductive material including molybdenum (Mo), aluminum (Al), copper (Cu), or titanium (Ti), and may have a single structure or a multi-layer structure including the above material. For example, each of the first connection electrode 1001, the first conductive pattern layer DL1a, and the second conductive pattern layer DL1b may have a multi-layer structure including Ti/Al/Ti.

The first connection electrode 1001 may be connected (e.g., electrically connected) to the fourth connection electrode 2001 through a contact hole formed in the sixth insulating layer 121. A part of the first connection electrode 1001 may be buried (or filled) in the contact hole, and the first connection electrode 1001 and the fourth connection electrode 2001 may be connected (e.g., electrically connected) to each other. The first connection electrode 1001 may be connected (e.g., electrically connected) to the first semiconductor layer Act1 through the fourth connection electrode 2001.

The first conductive pattern layer DL1a may be connected (e.g., electrically connected) to an end portion of the first connection pattern layer DL1c through the seventh contact hole cnt7 formed in the sixth insulating layer 121. A part of the first conductive pattern layer DL1a may be buried (or filled) in the seventh contact hole cnt7, and the first conductive pattern layer DL1a and the first connection pattern layer DL1c may be connected (e.g., electrically connected) to each other.

The second conductive pattern layer DL1b may be connected (e.g., electrically connected) to another end portion of the first connection pattern layer DL1c through the eighth contact hole cnt8 formed in the sixth insulating layer 121. A part of the second conductive pattern layer DL1b may be buried (or filled) in the eighth contact hole cnt8, and the second conductive pattern layer DL1b and the first connection pattern layer DL1c may be connected (e.g., electrically connected) to each other.

The first display element DE1 may be positioned on the seventh insulating layer 123. The first display element DE1 may include a first pixel electrode 210a, an intermediate layer 220 including an organic emission layer, and a counter electrode 230.

The first pixel electrode 210a may be a semi-transmissive electrode, a transmissive electrode, or a reflective electrode. In some embodiments, the first pixel electrode 210a may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent electrode layer or a semi-transparent electrode layer formed on the reflective layer. The transparent electrode layer or a semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). In some embodiments, the first pixel electrode 210a may include ITO/Ag/ITO.

The first pixel electrode 210a may be connected (e.g., electrically connected) to the first connection electrode 1001 through the first contact hole cnt1 formed in the seventh insulating layer 123. A part of the first pixel electrode 210a may be buried (or filled) in the first contact hole cnt1, and the first pixel electrode 210a and the first connection electrode 1001 may be connected (e.g., electrically connected) to each other. The first pixel electrode 210a may be electrically connected to the first semiconductor layer Act1 through the first connection electrode 1001 and the fourth connection electrode 2001.

The pixel-defining film 125 may be positioned on the seventh insulating layer 123. For example, the pixel-defining film 125 may increase a distance between an edge portion of the first pixel electrode 210a and the counter electrode 230 positioned over the first pixel electrode 210a, to prevent an arc or the like from occurring on the edge portion of the first pixel electrode 210a.

The pixel-defining film 125 may be formed of at least one organic insulating material selected from the group consisting of polyimide, polyamide, acrylic resin, benzocyclobutene, and phenolic resin by using spin coating or the like. The pixel-defining film 125 may include an organic insulating material. In another example, the pixel-defining film 125 may include an inorganic insulating material such as silicon nitride, silicon oxynitride, or silicon oxide. In another example, the pixel-defining film 125 may include an organic insulating material and an inorganic insulating material. In some embodiments, the pixel-defining film 125 may include a light-blocking material, and may be black. The light-blocking material may include carbon black, carbon nanotubes, a resin or paste including a black dye, metal particles such as nickel, aluminum, molybdenum, or an alloy thereof, metal oxide particles (e.g., chromium oxide), or metal nitride particles (e.g., chromium nitride). In case that the pixel-defining film 125 includes a light-blocking material, reflection of external light by metal structures positioned under the pixel-defining film 125 may be reduced.

The intermediate layer 220 may be positioned in the first opening OP1 formed by the pixel-defining film 125. The first opening OP1 may define the first emission area EA1 of the first display element DE1. The intermediate layer 220 may include an organic emission layer. The organic emission layer may include an organic material including a fluorescent or phosphorescent material that emits red, green, blue, or white light. The organic emission layer may be formed of a low-molecular-weight organic material or a high-molecular-weight organic material. A functional layer such as a hole transport layer (HTL), a hole injection layer (HIL), an electron transport layer (ETL), or an electron injection layer (EIL) may be selectively further positioned under or over the organic emission layer.

The intermediate layer 220 may be positioned to correspond to each of first pixel electrodes 210a. However, embodiments are not limited thereto. Various modifications may be made. For example, the intermediate layer 220 may include an integrated layer over the first pixel electrodes 210a.

The counter electrode 230 may be a light-transmitting electrode or a reflective electrode. In some embodiments, the counter electrode 230 may be a transparent electrode or a semi-transparent electrode and may include a metal thin film having a low work function including lithium (Li), calcium (Ca), LiF/Ca, LiF/Al, aluminum (Al), silver (Ag), magnesium (Mg), or a compound thereof. For example, a transparent conductive oxide (TCO) film such as ITO, IZO, ZnO, or In₂O₃ may be further positioned on the metal thin film. The counter electrode 230 may be positioned over the display area DA (see FIG. 1), and may be positioned on the intermediate layer 220 and the pixel-defining film 125. The counter electrode 230 may be integrally formed in first display elements DE1 to correspond to the first pixel electrodes 210a.

The first display element DE1 may be covered by an encapsulation layer. The encapsulation layer may include at least one organic encapsulation layer and at least one inorganic encapsulation layer. The at least one inorganic encapsulation layer may include at least one inorganic material from among aluminum oxide, titanium oxide, tantalum oxide, hafnium oxide, zinc oxide, silicon oxide, silicon nitride, and silicon oxynitride. The at least one inorganic encapsulation layer may have a single structure or a multi-layer structure including the above material. The at least one organic encapsulation layer may include a polymer-based material. Examples of the polymer-based material may include an acrylic resin such as polymethylmethacrylate or polyacrylic acid, an epoxy resin, polyimide, and polyethylene. In an embodiment, the at least one organic encapsulation layer may include an acrylate polymer.

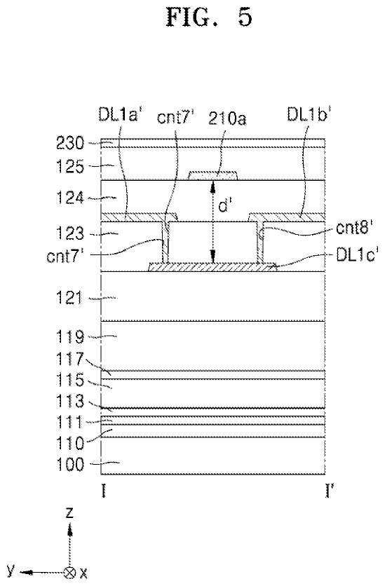

FIG. 5 is a schematic cross-sectional view of a pixel electrode and a data line of FIG. 3, taken along line I-I′. The embodiment of FIG. 5, as a modification of the embodiment of FIG. 4, is different from FIG. 4 in a structure of the first data line DL1. The same description as that made with reference to FIG. 4 will be omitted, and a difference will be described.

Referring to FIG. 5, the display apparatus 1 may further include an eighth insulating layer 124. The eighth insulating layer 124 may be positioned between the seventh insulating layer 123 and the pixel-defining film 125. The eighth insulating layer 124 may have a single structure or a multi-layer structure including an organic material to provide a flat top surface (or flat upper surface). The eighth insulating layer 124 may include benzocyclobutene (BCB), polyimide, hexamethyldisiloxane (HMDSO), a general-purpose polymer such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A first connection pattern layer DL1c′ may be positioned between the sixth insulating layer 121 and the seventh insulating layer 123, and a first conductive pattern layer DL1a′ and a second conductive pattern layer DL1b′ may be positioned between the seventh insulating layer 123 and the eighth insulating layer 124.

The first conductive pattern layer DL1a′ may be connected (e.g., electrically connected) to an end portion of the first connection pattern layer DL1c′ through a seventh contact hole cnt7′ formed in the seventh insulating layer 123. A part of the first conductive pattern layer DL1a′ may be buried (or filled) in the seventh contact hole ent7′, and the first conductive pattern layer DL1a′ and the first connection pattern layer DL1c′ may be connected (e.g., electrically connected) to each other.

The second conductive pattern layer DL1b′ may be connected (e.g., electrically connected) to another end portion of the first connection pattern layer DL1c′ through an eighth contact hole cnt8′ formed in the seventh insulating layer 123. A part of the second conductive pattern layer DL1b′ may be buried (or filled) in the eighth contact hole cnt8′, and the second conductive pattern layer DL1b′ and the first connection pattern layer DL1c′ may be connected (e.g., electrically connected) to each other.

For example, the first conductive pattern layer DL1a′ and the second conductive pattern layer DL1b′ may be positioned on the same layer (e.g., seventh insulating layer 123) between the first pixel electrode 210a and the first connection pattern layer DL1c′. For example, a distance d′ between the first data line DL1 and the first pixel electrode 210a may increase at a portion where the first data line DL1 and the first pixel electrode 210a overlap each other. Thus, a capacitance value formed between the first data line DL1 and the first pixel electrode 210a may decrease.

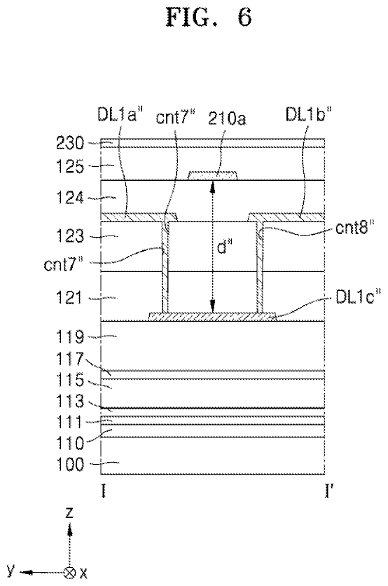

FIG. 6 is a schematic cross-sectional view of a pixel electrode and a data line of FIG. 3, taken along line I-I′. The embodiment of FIG. 6, as a modification of the embodiment of FIG. 5, is different from FIG. 5 in a structure of the first data line DL1. The same description as that made with reference to FIG. 5 will be omitted, and a difference will be described.

Referring to FIG. 6, a first connection pattern layer DL1c″ may be positioned between the fifth insulating layer 119 and the sixth insulating layer 121, and a first conductive pattern layer DL1a″ and a second conductive pattern layer DL1b″ may be positioned between the seventh insulating layer 123 and the eighth insulating layer 124.

The first conductive pattern layer DL1a″ may be connected (e.g., electrically connected) to an end portion of the first connection pattern layer DL1c″ through a seventh contact hole cnt7″ formed in the sixth insulating layer 121 and the seventh insulating layer 123. A part of the first conductive pattern layer DL1a″ may be buried (or filled) in the seventh contact hole cnt7″, and the first conductive pattern layer DL1a″ and the first connection pattern layer DL1c″ may be connected (e.g., electrically connected) to each other.

The second conductive pattern layer DL1b″ may be connected (e.g., electrically connected) to another end portion of the first connection pattern layer DL1c″ through an eighth contact hole cnt8″ formed in the sixth insulating layer 121 and the seventh insulating layer 123. A part of the second conductive pattern layer DL1b″ may be buried (or filled) in the eighth contact hole cnt8″, and the second conductive pattern layer DL1b″ and the first connection pattern layer DL1c″ may be connected (e.g., electrically connected) to each other.

For example, the first conductive pattern layer DL1a″ and the second conductive pattern layer DL1b″ may be positioned on the same layer (e.g., seventh insulating layer 123) between the first pixel electrode 210a and the first connection pattern layer DL1c“. For example, a distance d” between the first data line DL1 and the first pixel electrode 210a may increase at a portion where the first data line DL1 and the first pixel electrode 210a overlap each other. Thus, a capacitance value formed between the first data line DL1 and the first pixel electrode 210a may decrease.

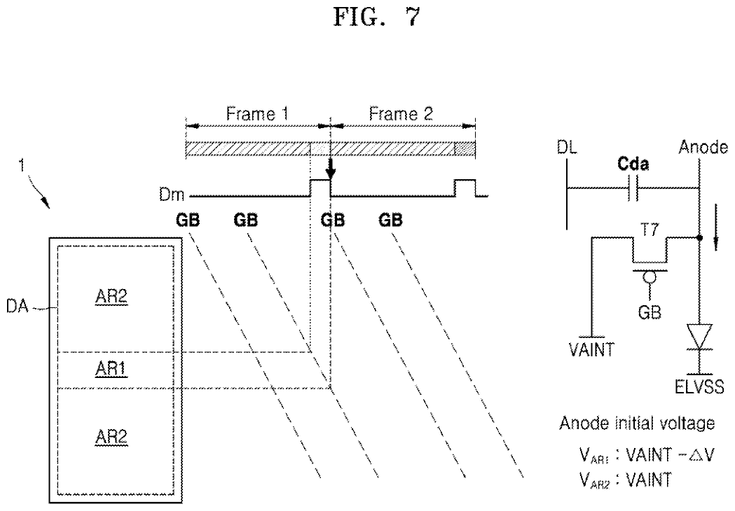

FIG. 7 is a schematic view of an operation of a display apparatus according to an embodiment.

Referring to a circuit diagram shown on the right side of FIG. 7, a capacitor Cda may be formed between the data line DL and the anode of the organic light-emitting diode OLED. The anode of the organic light-emitting diode OLED may be capacitively coupled to the data line DL by the capacitor Cda. In case that the seventh transistor T7 is turned on in response to the fourth scan signal GB and the second initialization voltage VAINT is applied to the anode of the organic light-emitting diode OLED, the anode of the organic light-emitting diode OLED may not be capacitively coupled to the data line DL by the capacitor Cda.

Referring to a timing diagram shown on the left side of FIG. 7, a cycle (see a dashed diagonal line) in which the seventh transistor T7 is turned on in response to the fourth scan signal GB may be repeated twice for one frame. For example, in case that the display apparatus 1 is driven at 120 Hz, a frequency of the fourth scan signal GB may be 240 Hz. For example, the display area DA of the display apparatus 1 may be divided into a first area AR1 where the seventh transistor T7 is turned on and a second area AR2 where the seventh transistor T7 is turned off, in response to the fourth scan signal GB, in case that a black voltage is applied to the data line DL (e.g., in case that the data voltage Dm has a rising edge). A potential of the anode of the organic light-emitting diode positioned in the first area AR1 is not affected by the rising edge of the data voltage Dm in case that the black voltage is applied to the data line DL to turn on the seventh transistor T7, but may decrease by a potential change amount ΔV due to a falling edge of the data voltage Dm by the capacitor Cda. Because the seventh transistor T7 is turned off in case that the black voltage is applied to the data line DL, a potential of the anode of the organic light-emitting diode OLED positioned in the second area AR2 may increase due to the rising edge of the data voltage Dm and may decrease due to the falling edge of the data voltage Dm by the capacitor Cda. Accordingly, a first anode initial voltage V_{AR1} of the first area AR1 may be a value VAINT-ΔV obtained by subtracting the potential change amount ΔV from the second initialization voltage VAINT, and a second anode initial voltage V_{AR2} of the second area AR2 may be the second initialization voltage VAINT. There is an anode initial voltage difference between the first area AR1 and the second area AR2, and stains may occur in the display area DA due to the anode initial voltage difference.

As described with reference to FIGS. 3 to 6 according to an embodiment, a capacitance value formed between the data line DL and the organic light-emitting diode OLED may decrease. In case that the capacitance value formed between the data line DL and the anode of the organic light-emitting diode OLED decreases, the potential change amount ΔV may decrease, and an anode initial voltage difference between the first area AR1 and the second area AR2 may decrease. Accordingly, stains may be prevented from occurring in the display area DA due to an anode initial voltage difference.

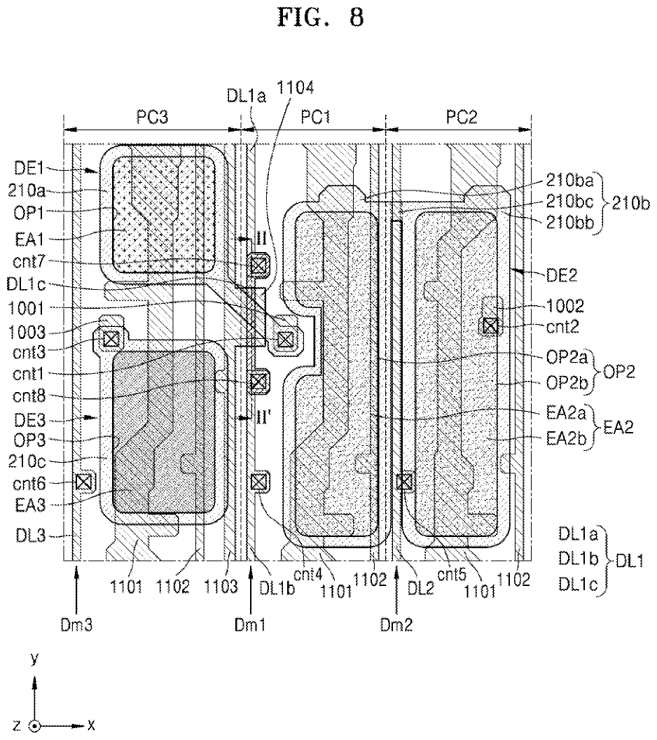

FIG. 8 is an enlarged schematic plan view of a portion of a display apparatus according to an embodiment. The embodiment of FIG. 8, as a modification of the embodiment of FIG. 3, is different from FIG. 3 in a structure of a shield electrode. The same description as that made with reference to FIG. 3 will be omitted, and a difference will be described.

Referring to FIG. 8, the display apparatus 1 may further include a first shield electrode 1104. The first shield electrode 1104 may be positioned between the first display element DE1 and the first connection pattern layer DL1c. The first shield electrode 1104 may be positioned between the first pixel electrode 210a and the first connection pattern layer DL1c. The first shield electrode 1104, the first conductive pattern layer DL1a, and the second conductive pattern layer DL1b may be positioned on the same layer.

The first shield electrode 1104 may at least partially overlap the first connection pattern layer DL1c. The first shield electrode 1104 may at least partially overlap the first pixel electrode 210a. A preset (or certain) voltage may be applied to the first shield electrode 1104. For example, the first shield electrode 1104 may extend from the third conductive line 1103 in a second direction (e.g., ±x-axis direction). The first shield electrode 1104 and the third conductive line 1103 may be integral (or integrally formed) with each other. As described with reference to FIG. 3, because the first initialization voltage VINT, the second initialization voltage VAINT, or the bias voltage VOBS of FIG. 2 may be applied to the third conductive line 1103, the first initialization voltage VINT, the second initialization voltage VAINT, or the bias voltage VOBS may be applied to the first shield electrode 1104.

As in an embodiment, in case that the first shield electrode 1104 to which a preset (or certain) voltage is applied is positioned between the first pixel electrode 210a and the first connection pattern layer DL1c, a capacitance value formed between the first data line DL1 and the first pixel electrode 210a may decrease. As the capacitance value formed between the first data line DL1 and the first pixel electrode 210a decreases, stains may be prevented from occurring in the display area DA (see FIG. 1).

Although the first shield electrode 1104 and the third conductive line 1103 are integral (or integrally formed) with each other in FIG. 8, in another example, the first shield electrode 1104 and the third conductive line 1103 may be separated from each other. The first shield electrode 1104 may be electrically connected to the first conductive line 1101 or the second conductive line 1102 so that a preset (or certain) voltage may be applied to the first shield electrode 1104.

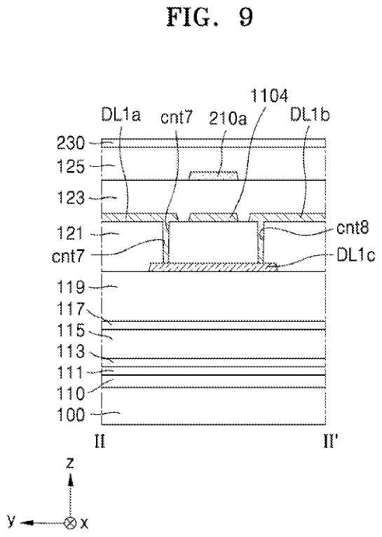

FIG. 9 is a schematic cross-sectional view of a pixel electrode, a data line, and a shield electrode of FIG. 8, taken along line II-II′. In FIG. 9, the same members as those in FIG. 4 are denoted by the same reference numerals, and thus, a redundant description thereof will be omitted for descriptive convenience.

Referring to FIG. 9, the first shield electrode 1104 may be positioned between the first pixel electrode 210a and the first connection pattern layer DL1c. The first shield electrode 1104, the first conductive pattern layer DL1a, and the second conductive pattern layer DL1b may be positioned on the same layer. For example, as shown in FIG. 9, the first shield electrode 1104 may be positioned between the sixth insulating layer 121 and the seventh insulating layer 123.

Although the first shield electrode 1104 is positioned between the sixth insulating layer 121 and the seventh insulating layer 123 in FIG. 9, in another example according to FIGS. 5 and 6, the first shield electrode 1104 may be positioned between the seventh insulating layer 123 and the eighth insulating layer 124.

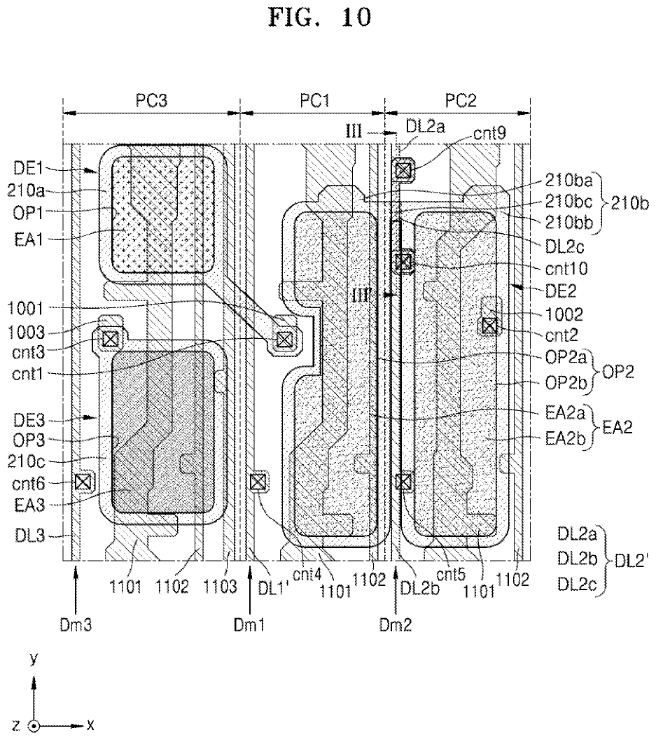

FIG. 10 is an enlarged schematic plan view of a portion of a display apparatus 1 according to an embodiment. The embodiment of FIG. 10, as a modification of the embodiment of FIG. 3, is different from FIG. 3 in structures of the first data line DL1′ and the second data line DL2′. The same description as that made with reference to FIG. 3 will be omitted, and a difference will be described.

Referring to FIG. 10, the first data line DL1′ may continuously extend in the first direction (e.g., ±y-axis direction), like the third data line DL3. A second data line DL2′ may include a third conductive pattern layer DL2a, a fourth conductive pattern layer DL2b, and a second connection pattern layer DL2c. The third conductive pattern layer DL2a and a fourth conductive pattern layer DL2b may extend in the first direction (e.g., ±y-axis direction) to be spaced apart from each other. The second connection pattern layer DL2c may extend in the first direction (e.g., ±y-axis direction) to connect (e.g., electrically connect) the third conductive pattern layer DL2a to the fourth conductive pattern layer DL2b. An end portion of the second connection pattern layer DL2c may be connected (e.g., electrically connected) to the third conductive pattern layer DL2a through a ninth contact hole cnt9, and another end portion of the second connection pattern layer DL2c may be connected (e.g., electrically connected) to the fourth conductive pattern layer DL2b through a tenth contact hole cnt10. In a plan view, the third conductive pattern layer DL2a and the fourth conductive pattern layer DL2b may be spaced apart from (may not overlap) the second pixel electrode 210b, and the second connection pattern layer DL2c may at least partially overlap the second pixel electrode 210b. The second connection pattern layer DL2c may at least partially overlap the third electrode portion 210bc of the second pixel electrode 210b.

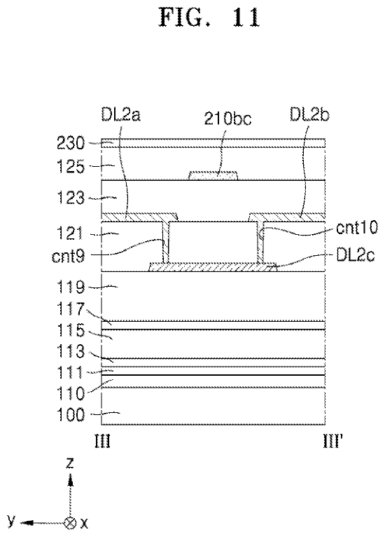

As shown in FIG. 11, the third conductive pattern layer DL2a and the fourth conductive pattern layer DL2b may be positioned on the same layer (e.g., sixth insulating layer 121) between the second pixel electrode 210b and the second connection pattern layer DL2c. For example, a distance between the second data line DL2′ and the second pixel electrode 210b may increase at a portion where the second data line DL2′ and the second pixel electrode 210b overlap each other. Thus, a capacitance value formed between the second data line DL2′ and the second pixel electrode 210b may decrease. For example, in case that the second pixel electrode 210b includes the first electrode portion 210ba and the second electrode portion 210bb that are spaced apart from each other with the second data line DL2′ therebetween, an overlapping ratio (or overlapping size/area) between the second data line DL2′ and the second pixel electrode 210b may decrease, and thus, the capacitance value formed between the second data line DL2′ and the second pixel electrode 210b may decrease. As the capacitance value formed between the second data line DL2′ and the second pixel electrode 210b decreases, stains may be prevented from occurring in the display area DA (see FIG. 1).

FIG. 11 is a schematic cross-sectional view of a pixel electrode and a data line of FIG. 10, taken along line III-III′. In FIG. 11, the same members as those in FIG. 4 are denoted by the same reference numerals, and thus, a redundant description thereof will be omitted for descriptive convenience.

Referring to FIG. 11, the second connection pattern layer DL2c may be positioned between the fifth insulating layer 119 and the sixth insulating layer 121, and the third conductive pattern layer DL2a and the fourth conductive pattern layer DL2b may be positioned between the sixth insulating layer 121 and the seventh insulating layer 123.

The third conductive pattern layer DL2a may be connected (e.g., electrically connected) to an end portion of the second connection pattern layer DL2c through the ninth contact hole cnt9 formed in the sixth insulating layer 121. A part of the third conductive pattern layer DL2a may be buried (or filled) in the ninth contact hole cnt9, and the third conductive pattern layer DL2a and the second connection pattern layer DL2c may be connected (e.g., electrically connected) to each other.

The fourth conductive pattern layer DL2b may be connected (e.g., electrically connected) to another end portion of the second connection pattern layer DL2c through the tenth contact hole cnt10 formed in the sixth insulating layer 121. A part of the fourth conductive pattern layer DL2b may be buried (or filled) in the tenth contact hole cnt10, and the fourth conductive pattern layer DL2b and the second connection pattern layer DL2c may be connected (e.g., electrically connected) to each other.

Referring to FIG. 11, the second connection pattern layer DL2c may be positioned between the fifth insulating layer 119 and the sixth insulating layer 121, and the third conductive pattern layer DL2a and the fourth conductive pattern layer DL2b may be positioned between the sixth insulating layer 121 and the seventh insulating layer 123 in FIG. 11. In another example, as shown in FIG. 5, the second connection pattern layer DL2c may be positioned between the sixth insulating layer 121 and the seventh insulating layer 123, and the third conductive pattern layer DL2a and the fourth conductive pattern layer DL2b may be positioned between the seventh insulating layer 123 and the eighth insulating layer 124. For example, the ninth contact hole cnt9 and the tenth contact hole cnt10 may be formed in the seventh insulating layer 123.

In another example, as shown in FIG. 6, the second connection pattern layer DL2c may be positioned between the fifth insulating layer 119 and the sixth insulating layer 121 and the third conductive pattern layer DL2a and the fourth conductive pattern layer DL2b may be positioned between the seventh insulating layer 123 and the eighth insulating layer 124. For example, the ninth contact hole cnt9 and the tenth contact hole cnt10 may be formed in the sixth insulating layer 121 and the seventh insulating layer 123.

FIG. 12 is an enlarged schematic plan view of a portion of a display apparatus according to an embodiment. The embodiment of FIG. 12, as a modification of the embodiment of FIG. 10, is different from FIG. 10 in a structure of the second display element DE2. The same description as that made with reference to FIG. 10 will be omitted, and a difference will be described.

Referring to FIG. 12, the second pixel electrode 210b of the second display element DE2 may include the first electrode portion 210ba, the second electrode portion 210bb, and the third electrode portion 210bc. The first electrode portion 210ba and the second electrode portion 210bb may extend in the first direction (e.g., +y-axis direction). The first electrode portion 210ba and the second electrode portion 210bb may be spaced apart from each other with the second data line DL2′ therebetween. The third electrode portion 210bc may connect (e.g., electrically connect) the first electrode portion 210ba to the second electrode portion 210bb. The third electrode portion 210bc may connect (e.g., electrically connect) a central portion of the first electrode portion 210ba to a central portion of the second electrode portion 210bb.

For example, because only the third electrode portion 210bc overlaps the second data line DL2′, an overlapping ratio (or overlapping size/area) between the second data line DL2′ and the second pixel electrode 210b may decrease. Because an overlapping ratio (or overlapping size/area) between the second data line DL2′ and the second pixel electrode 210b decreases, a capacitance value formed between the second data line DL2′ and the second pixel electrode 210b may decrease. As the capacitance value formed between the second data line DL2′ and the second pixel electrode 210b decreases, stains may be prevented from occurring in the display area DA (see FIG. 1).

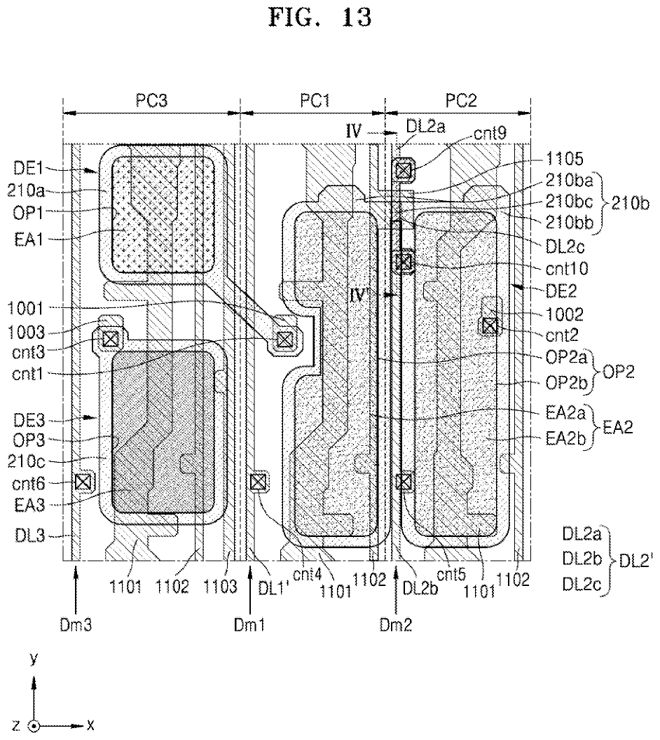

FIG. 13 is an enlarged schematic plan view of a portion of a display apparatus according to an embodiment. The embodiment of FIG. 13, as a modification of the embodiment of FIG. 10, is different from FIG. 10 in a structure of a shield electrode. The same description as that made with reference to FIG. 10 will be omitted, and a difference will be described.

Referring to FIG. 13, the display apparatus 1 may further include a second shield electrode 1105. The second shield electrode 1105 may be positioned between the second display element DE2 and the second connection pattern layer DL2c. The second shield electrode 1105 may be positioned between the second pixel electrode 210b and the second connection pattern layer DL2c. The second shield electrode 1105, the third conductive pattern layer DL2a, and the fourth conductive pattern layer DL2b may be positioned on the same layer.

The second shield electrode 1105 may at least partially overlap the second connection pattern layer DL2c. The second shield electrode 1105 may at least partially overlap the second pixel electrode 210b. A preset (or certain) voltage may be applied to the second shield electrode 1105. For example, the second shield electrode 1105 may extend from the second conductive line 1102 in the second direction (e.g., +x-axis direction). The second shield electrode 1105 and the second conductive line 1102 may be integral (or integrally formed) with each other. As described with reference to FIG. 3, because the second driving voltage ELVSS may be applied to the third conductive line 1103, the second driving voltage ELVSS may be applied to the second shield electrode 1105.

As in an embodiment, in case that the second shield electrode 1105 is positioned between the second pixel electrode 210b and the second connection pattern layer DL2c, a capacitance value formed between the second data line DL2′ and the second pixel electrode 210b may decrease. As the capacitance value formed between the second data line DL2′ and the second pixel electrode 210b decreases, stains may be prevented from occurring in the display area DA (see FIG. 1).

Although the second shield electrode 1105 and the second conductive line 1102 are integral (or integrally formed) with each other in FIG. 13, in another example, the second shield electrode 1105 and the second conductive line 1102 may be separated from each other. The second shield electrode 1105 may be electrically connected to the first conductive line 1101 or the third conductive line 1103 so that a preset (or certain) voltage may be applied to the second shield electrode 1105.

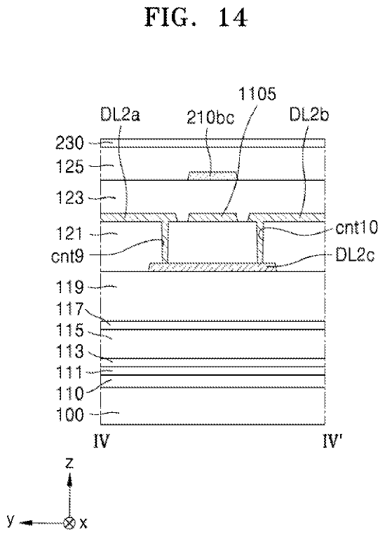

FIG. 14 is a schematic cross-sectional view of a pixel electrode, a data line, and a shield electrode of FIG. 13, taken along line IV-IV′. In FIG. 14, the same members as those in FIG. 4 are denoted by the same reference numerals, and thus, a redundant description thereof will be omitted for descriptive convenience.

Referring to FIG. 14, the second shield electrode 1105 may be positioned between the third electrode portion 210bc of the second pixel electrode 210b and the second connection pattern layer DL2c. The second shield electrode 1105, the third conductive pattern layer DL2a, and the fourth conductive pattern layer DL2b may be positioned on the same layer. For example, as shown in FIG. 14, the second shield electrode 1105 may be positioned between the sixth insulating layer 121 and the seventh insulating layer 123.

Referring to FIG. 14, the second shield electrode 1105 may be positioned between the sixth insulating layer 121 and the seventh insulating layer 123 in FIG. 14. In another example, according to FIGS. 5 and 6, the second shield electrode 1105 may be positioned between the seventh insulating layer 123 and the eighth insulating layer 124.

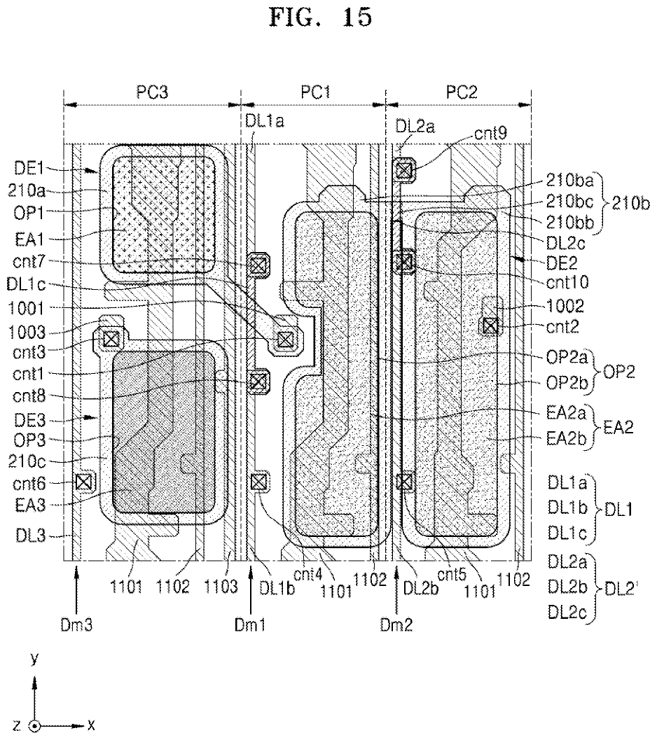

FIG. 15 is an enlarged schematic plan view of a portion of a display apparatus according to an embodiment. The embodiment of FIG. 15, as a modification of the embodiment of FIG. 3, is different from FIG. 3 in a structure of the second data line DL2′. The same description as that made with reference to FIG. 3 will be omitted, and a difference will be described.

Referring to FIG. 15, an embodiment of FIG. 3 and an embodiment of FIG. 10 may be applied together. The first data line DL1 may include the first conductive pattern layer DL1a, the second conductive pattern layer DL1b, and the first connection pattern layer DL1c. The first conductive pattern layer DL1a and the second conductive pattern layer DL1b may extend in the first direction (e.g., +y-axis direction) to be spaced apart from each other. The first connection pattern layer DL1c may extend in the first direction (e.g., +y-axis direction) to connect (e.g., electrically connect) the first conductive pattern layer DL1a to the second conductive pattern layer DL1b. An end portion of the first connection pattern layer DL1c may be connected (e.g., electrically connected) to the first conductive pattern layer DL1a through the seventh contact hole cnt7, and another end portion of the first connection pattern layer DL1c may be connected (e.g., electrically connected) to the second conductive pattern layer DL1b through the eighth contact hole cnt8. In a plan view, the first conductive pattern layer DL1a and the second conductive pattern layer DL1b may be spaced apart from (may not overlap) the first pixel electrode 210a, and the first connection pattern layer DL1c may at least partially overlap the first pixel electrode 210a.

The second data line DL2′ may include the third conductive pattern layer DL2a, the fourth conductive pattern layer DL2b, and the second connection pattern layer DL2c. The third conductive pattern layer DL2a and the fourth conductive pattern layer DL2b may extend in the first direction (e.g., +y-axis direction) to be spaced apart from each other. The second connection pattern layer DL2c may extend in the first direction (e.g., +y-axis direction) to connect (e.g., electrically connect) the third conductive pattern layer DL2a to the fourth conductive pattern layer DL2b. An end portion of the second connection pattern layer DL2c may be connected (e.g., electrically connected) to the third conductive pattern layer DL2a through the ninth contact hole cnt9, and another end portion of the second connection pattern layer DL2c may be connected (e.g., electrically connected) to the fourth conductive pattern layer DL2b through the tenth contact hole cnt10. In a plan view, the third conductive pattern layer DL2a and the fourth conductive pattern layer DL2b may be spaced apart from (may not overlap) the second pixel electrode 210b, and the second connection pattern layer DL2c may at least partially overlap the second pixel electrode 210b. The second connection pattern layer DL2c may at least partially overlap the third electrode portion 210bc of the second pixel electrode 210b.

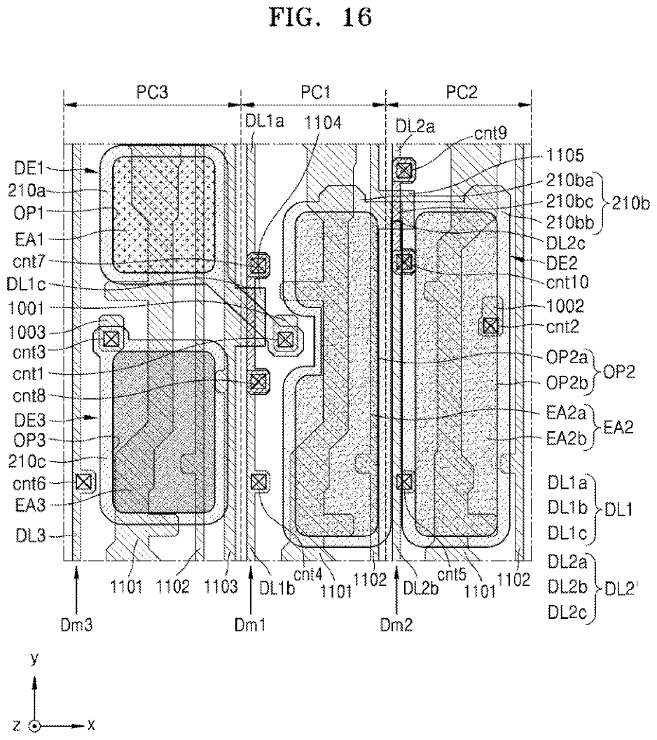

FIG. 16 is an enlarged schematic plan view of a portion of a display apparatus according to an embodiment. The embodiment of FIG. 16, as a modification of the embodiment of FIG. 15, is different from FIG. 15 in a structure of a shield electrode. The same description as that made with reference to FIG. 15 will be omitted, and a difference will be described.

Referring to FIG. 16, an embodiment of FIG. 8 and an embodiment of FIG. 13 may be applied together. The display apparatus 1 may further include the first shield electrode 1104 and the second shield electrode 1105.

The first shield electrode 1104 may be positioned between the first display element DE1 and the first connection pattern layer DL1c. The first shield electrode 1104 may be positioned between the first pixel electrode 210a and the first connection pattern layer DL1c. The first shield electrode 1104, the first conductive pattern layer DL1a, and the second conductive pattern layer DL1b may be positioned on the same layer. The first shield electrode 1104 may at least partially overlap the first connection pattern layer DL1c. The first shield electrode 1104 may at least partially overlap the first pixel electrode 210a. A first voltage may be applied to the first shield electrode 1104. For example, the first shield electrode 1104 may extend from the third conductive line 1103 in the second direction (e.g., +x-axis direction). The first shield electrode 1104 and the third conductive line 1103 may be integral (or integrally formed) with each other. As described with reference to FIG. 3, because the first initialization voltage VINT, the second initialization voltage VAINT, or the bias voltage VOBS may be applied to the third conductive line 1103, the first initialization voltage VINT, the second initialization voltage VAINT, or the bias voltage VOBS may be applied to the first shield electrode 1104.

The second shield electrode 1105 may be positioned between the second display element DE2 and the second connection pattern layer DL2c. The second shield electrode 1105 may be positioned between the second pixel electrode 210b and the second connection pattern layer DL2c. The second shield electrode 1105 may be positioned on the same layer as the third conductive pattern layer DL2a and the fourth conductive pattern layer DL2b. The second shield electrode 1105 may at least partially overlap the second connection pattern layer DL2c. The second shield electrode 1105 may at least partially overlap the second pixel electrode 210b. A second voltage may be applied to the second shield electrode 1105. For example, the second shield electrode 1105 may extend from the second conductive line 1102 in the second direction (e.g., ±x-axis direction). The second shield electrode 1105 and the second conductive line 1102 may be integral (or integrally formed) with each other. As described with reference to FIG. 3, the second driving voltage ELVSS of FIG. 2 may be applied to the third conductive line 1103, the second driving voltage ELVSS may be applied to the second shield electrode 1105.

In an embodiment, the first voltage and the second voltage may be different from each other. For example, the first voltage may be the first initialization voltage VINT, the second initialization voltage VAINT, or the bias voltage VOBS, and the second voltage may be the second driving voltage ELVSS.

Although the first shield electrode 1104 and the third conductive line 1103 are integral (or integrally formed) with each other in FIG. 16, in another example, the first shield electrode 1104 and the third conductive line 1103 may be separated from each other. The first shield electrode 1104 may be electrically connected to the first conductive line 1101 or the second conductive line 1102 so that the first voltage may be applied to the first shield electrode 1104. Although the second shield electrode 1105 and the second conductive line 1102 are integral (or integrally formed) with each other in FIG. 16, in another example, the second shield electrode 1105 and the second conductive line 1102 may be separated from each other. The second shield electrode 1105 may be electrically connected to the first conductive line 1101 or the third conductive line 1103 so that the second voltage may be applied to the second shield electrode 1105.

A display apparatus 1 has been described, but embodiments are not limited thereto. For example, a method of manufacturing the display apparatus 1 may fall within the scope of the disclosure.

According to various embodiments, stains may be prevented from occurring in a display area. Accordingly, defects of a display apparatus may be prevented. However, the scope of the disclosure is not limited by these effects.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display apparatus comprising:
a first display element comprising a first pixel electrode, the first display element that emits light of a first color;
a first conductive pattern layer and a second conductive pattern layer extending in a first direction and spaced apart from each other; and
a first connection pattern layer extending in the first direction and electrically connecting the first conductive pattern layer to the second conductive pattern layer, the first connection pattern layer at least partially overlapping the first pixel electrode of the first display element,
wherein the first conductive pattern layer and the second conductive pattern layer are disposed on a same layer between the first display element and the first connection pattern layer.

2. The display apparatus of claim 1, further comprising:
a first data line that transmits a first data voltage, the first data line comprising the first conductive pattern layer, the second conductive pattern layer, and the first connection pattern layer; and
a first pixel circuit electrically connected to the first data line, the first pixel circuit that receives the first data voltage through the first data line and drives the first display element.

3. The display apparatus of claim 2, wherein
the first display element comprises a first emission area that emits light of the first color, and
in a plan view, the first pixel circuit and the first emission area of the first display element are spaced apart from each other.

4. The display apparatus of claim 3, further comprising:
a second display element comprising a second emission area and a second pixel electrode, the second emission area that emits light of a second color different from the first color;
a second data line that transmits a second data voltage, the second data line comprising:
a third conductive pattern layer extending in the first direction,
a fourth conductive pattern layer extending in the first direction and being spaced apart from the third conductive pattern layer, and
a second connection pattern layer extending in the first direction, the second connection pattern layer electrically connecting the third conductive pattern layer to the fourth conductive pattern layer and at least partially overlapping the second pixel electrode of the second display element; and
a second pixel circuit electrically connected to the second data line, the second pixel circuit that receives the second data voltage and drives the second display element, wherein
the third conductive pattern layer and the fourth conductive pattern layer are disposed on a same layer between the second display element and the second connection pattern layer, and
in a plan view, the second pixel circuit and the second emission area of the second display element at least partially overlap each other.

5. The display apparatus of claim 4, wherein
the second pixel electrode of the second display element comprises a first electrode portion, a second electrode portion, and a third electrode portion,
the first electrode portion and the second electrode portion extend in the first direction and spaced apart from each other with the second data line between the first electrode portion and the second electrode portion, and
the third electrode portion electrically connects the first electrode portion to the second electrode portion and at least partially overlaps the second connection pattern layer.

6. The display apparatus of claim 5, wherein
the second emission area of the second display element comprises:
a first light-emitting portion overlapping the first electrode portion in a plan view, and
a second light-emitting portion overlapping the second electrode portion in a plan view,
the first light-emitting portion overlaps the first pixel circuit in a plan view, and
the second light-emitting portion overlaps the second pixel circuit in a plan view.

7. The display apparatus of claim 5, wherein the third electrode portion electrically connects an end portion of the first electrode portion to an end portion of the second electrode portion.

8. The display apparatus of claim 5, wherein the third electrode portion electrically connects a central portion of the first electrode portion to a central portion of the second electrode portion.

9. The display apparatus of claim 4, further comprising:
a first shield electrode at least partially overlapping the first connection pattern layer; and
a second shield electrode at least partially overlapping the second connection pattern layer, wherein
the first shield electrode, the first conductive pattern layer, and the second conductive pattern layer are disposed on a same layer, and
the second shield electrode, the third conductive pattern layer, and the fourth conductive pattern layer are disposed on a same layer.

10. The display apparatus of claim 9, further comprising:
a first conductive line that transmits a first voltage, the first conductive line extending in the first direction; and
a second conductive line that transmits a second voltage, the second conductive line extending in the first direction, wherein
the first shield electrode extends from the first conductive line in a second direction intersecting the first direction, and
the second shield electrode extends from the second conductive line in the second direction.

11. The display apparatus of claim 10, wherein the first voltage and the second voltage are different from each other.

12. The display apparatus of claim 2, wherein the first pixel circuit comprises:
a first transistor that controls a magnitude of a driving current flowing through the first display element;
a second transistor that transmits the first data voltage to the first transistor in response to a first scan signal; and
a third transistor that transmits an initialization voltage to the first pixel electrode of the first display element in response to a second scan signal,
wherein a frequency of the first scan signal is different from a frequency of the second scan signal.

13. The display apparatus of claim 12, wherein the frequency of the second scan signal is higher than the frequency of the first scan signal.

14. The display apparatus of claim 1, wherein, in a plan view, the first conductive pattern layer and the second conductive pattern layer are spaced apart from the first pixel electrode of the first display element.

15. The display apparatus of claim 1, further comprising:
a shield electrode that transmits a voltage and at least partially overlaps the first connection pattern layer,
wherein the shield electrode, the first conductive pattern layer, and the second conductive pattern layer are disposed on a same layer.

16. The display apparatus of claim 15, further comprising:
a conductive line that transmits the voltage, the conductive line extending in the first direction, wherein
the shield electrode extends from the conductive line in a second direction intersecting the first direction, and
the shield electrode and the conductive line are integral with each other.

17. A display apparatus comprising:
a data line comprising:
a first conductive pattern layer extend in a first direction,
a second conductive pattern layer extend in the first direction and spaced apart from the first conductive pattern layer, and
a connection pattern layer extending in the first direction and electrically connecting the first conductive pattern layer to the second conductive pattern layer; and
a pixel electrode comprising:
a first electrode portion and a second electrode portion spaced apart from each other with the data line between the first electrode portion and the second electrode portion, and
a third electrode portion electrically connecting the first electrode portion to the second electrode portion and at least partially overlapping the connection pattern layer,
wherein the first conductive pattern layer and the second conductive pattern layer are disposed on a same layer between the pixel electrode and the connection pattern layer.

18. The display apparatus of claim 17, further comprising:
a display element comprising the pixel electrode; and
a pixel circuit that drives the display element, wherein
the pixel circuit comprises:
a first transistor that controls a magnitude of a driving current flowing through the display element;
a second transistor that electrically connects the data line to the first transistor in response to a first scan signal; and
a third transistor that transmits an initialization voltage to the pixel electrode of the display element in response to a second scan signal, and
a frequency of the first scan signal is different from a frequency of the second scan signal.

19. The display apparatus of claim 18, wherein the frequency of the second scan signal is higher than the frequency of the first scan signal.

20. The display apparatus of claim 18, wherein, in a plan view, the pixel circuit at least partially overlaps the first electrode portion or the second electrode portion.

21. The display apparatus of claim 17, wherein the third electrode portion electrically connects an end portion of the first electrode portion to an end portion of the second electrode portion.

22. The display apparatus of claim 17, wherein the third electrode portion electrically connects a central portion of the first electrode portion to a central portion of the second electrode portion.

23. The display apparatus of claim 17, wherein, in a plan view, the first conductive pattern layer and the second conductive pattern layer are spaced apart from the pixel electrode.

24. The display apparatus of claim 17, further comprising:
a shield electrode that transmits a voltage and at least partially overlaps the connection pattern layer,
wherein the shield electrode, the the first conductive pattern layer, and the second conductive pattern layer are disposed on a same layer.

25. The display apparatus of claim 24, further comprising:
a conductive line that transmits the voltage, the conductive line extending in the first direction, wherein
the shield electrode extends from the conductive line in a second direction intersecting the first direction, and
the shield electrode and the conductive line are integral with each other.
